(19) United States
(12) Patent Application Publication
(10) Pub. No.: US 2006/0139706 A1
(43) Pub. Date: Jun. 29, 2006

(54) Display processing apparatus

(75) Inventor: Atsushi Kotani, Kanagawa (JP)

Correspondence Address: MCDERMOTT WILL & EMERY LLP, 600 13TH STREET, N.W., WASHINGTON, DC, 20005-3096, US

(73) Assignee: MATSUSHITA ELECTRIC INDUSTRIAL CO., LTD.

(21) Appl. No.: 11/316,995

(22) Filed: Dec. 27, 2005

(30) Foreign Application Priority Data
Dec. 27, 2004 (JP) 2004-376074
Nov. 17, 2005 (JP) 2005-332762

(51) Int. Cl. G03F 3/08

(52) U.S. Cl. 358/518

(57) ABSTRACT

A display processing apparatus has a color correcting unit for performing color correction with respect to display data, a color correction cancelled position setting unit for outputting information (correction cancelled position information) indicative of the position of a part of the display data which does not require the color correction, and a color correction canceling unit for canceling the color correction of the part of the display data color-corrected by the color correcting unit which corresponds to the correction cancelled position information.

### CROSS-REFERENCE TO RELATED APPLICATIONS

This Nonprovisional application claims priority under 35 U.S.C. § 119(a) on Patent Application No. 2004-376074 filed in Japan on Dec. 27, 2004, the entire contents of which are hereby incorporated by reference. The entire contents of Patent Application No. 2005-332762 filed in Japan on Dec. 17, 2005, are also incorporated by reference.

### BACKGROUND OF THE INVENTION

1. Field of the Invention

The present invention relates to a display processing apparatus having a color correcting function for improving the visibility of displayed data.

2. Description of the Prior Art

Display processing apparatus for outputting display data to a display unit or the like include one having a mechanism for color correction (color correcting function) to improve the visibility of displayed data when the content of display is hard to be recognized or the like.

As a conventional display processing apparatus having a color correcting function, there has been known one which performs color correction with respect to the entire screen to be displayed (see FIG. 6). Specifically, a commercialized product has also been published (e.g., FPD Interface LSI for UXGA j-L0011 available from JEPICO Corporation AP Business Promotion Department Video & Image Media Group. See the Internet URL: http://wwwjepico.co.jp/product/ap/japanese/index.html).

In the display processing apparatus shown by way of example in FIG. 6, display data is outputted from a camera image input unit 602, a graphic output unit 603, or another image data source and inputted to an image quality correcting unit 600. The image quality correcting unit 600, to which a CPU 601 has set a parameter for color correction, performs color correction with respect to the entire screen in accordance with the set parameter and outputs the color-corrected display data to a display unit 604. Thus, when the entire screen being displayed is dark and the displayed object is hard to be recognized, e.g., the conventional display processing apparatus has performed the color correction with respect to the entire screen such that the color of the entire screen is brightened, thereby improving the visibility.

However, in the case where the conventional display processing apparatus having the color correcting function is applied to a system which requires multi-window display or the like, the color correction is performed disadvantageously to the entire screen even when it is intended for only one of windows. This has caused the problem that the visibility of another window, which does not require the color correction, lowers under the influence of the color correction.

### SUMMARY OF THE INVENTION

The present invention has been achieved in view of the foregoing problem and it is therefore an object of the present invention to prevent or reduce, even when color correction is performed to improve the visibility of one part of a screen in a display processing apparatus having a color correcting function, the lowering of the visibility of another part of the screen which does not require the color correction.

To attain the object, the present invention is a display processing apparatus comprising: a color correcting unit for performing color correction with respect to display data; a color correction cancelled position setting unit for outputting correction cancelled position information indicative of a position of a part of the display data which does not require the color correction; and a color correction canceling unit for canceling the color correction of the part of the display data color-corrected by the color correcting unit which corresponds to the correction cancelled position information.

In the arrangement, when the color correction is required for only one part of a display screen, the color correction of the other part of the display screen which does not require the color correction is cancelled. As a result, it becomes possible to prevent the lowering of the visibility of the part which does not require the color correction.

In one aspect, the present invention is a display processing apparatus comprising: a semi-transmission processing unit for receiving display data sets in a plurality of layers and performing a semi-transmission process to adjust a transmissivity of each of the inputted layers to a specified value; a synthesizing unit for superimposing the display data sets in the individual layers on each other to which the semi-transmission processing unit has performed the semi-transmission process and thereby generating new display data; a color correcting unit for performing color correction with respect to the new display data; a correction position control unit for outputting correction cancelled position information indicative of a position of a part of the new display data which does not require the color correction; and a color-correction-reducing-layer generating unit for outputting data in a color correction reducing layer composed of data for reducing an effect of the color correction at the part corresponding to the correction cancelled position information.

In the arrangement, the color correction reducing layer for reducing the effect of the color correction is synthesized. As a result, it becomes possible to reduce the lowering of the visibility of the part of the display screen which does not require the color correction when only one part of the display screen requires the color correction.

In the display processing apparatus in the foregoing aspect of the present invention, the color-correction-reducing-layer generating unit selects either of data in a color correction reducing layer composed of black color data and data in a color correction reducing layer composed of white color data and outputs the selected data to the semi-transmission processing unit.

The arrangement allows, when only one part of the display screen particularly requires brightness control as the color correction, a reduced change in the brightness of the part of the display screen which does not require the brightness control.

In the display processing apparatus in the foregoing aspect of the present invention, the color correcting unit performs the color correction by changing a value of a specified correction parameter for changing a visibility of displayed data and outputs the correction parameter to the semi-transmission processing unit and the semi-transmission processing unit determines the transmissivity in accordance with the correction parameter outputted from the color correcting unit.

Since the arrangement controls the transmissivity with the correction parameter used for the color correction, when the effect of a color change on one part of the display screen is dynamically controlled, e.g., the effect on the part of the display screen which does not require the color correction can also be dynamically reduced.

The display processing apparatus in the foregoing aspect of the present invention further comprises: a layer color control unit for determining, in accordance with the color correction performed in the color correcting unit, a color of the color correction reducing layer by combining three primary colors of red, green, and blue, wherein the color-correction-reducing-layer generating unit generates the color correction reducing layer in the color determined by the layer color control unit.

When the color correction is independently controlled over red, green, and blue as the three primary colors of light, the color correction reducing layer in a color in accordance with the color correction can be generated.

In the display processing apparatus in the foregoing aspect of the present invention, the display data is motion-picture data and the color correcting unit performs the color correction at a specified time interval.

The arrangement allows the color correction to be performed at the specified time interval. As a result, it becomes possible to reduce flickering observed at the part of the display screen which does not require the color correction when the brightness of one part of the screen to which the color correction is performed changes at extremely short intervals or the like.

In the display processing apparatus in the foregoing aspect of the present invention, the display data is motion-picture data and the color correcting unit performs the color correction at a specified time interval.

The arrangement stepwise controls the color change so that it becomes possible to reduce a sudden brightness change when there is a great difference between a pre-correction color and a post-correction color.

In the display processing apparatus in the foregoing aspect of the present invention, the synthesizing unit performs the superimposition in synchronization with the color correction in the color correcting unit.

The arrangement allows a color correction reduction to be performed in synchronization with the color correction process. Accordingly, it becomes possible to reduce the lowering of the visibility by performing the color correction reduction with respect to the part of the display screen which does not require the color correction when necessary.

In another aspect, the present invention is a display processing apparatus comprising: a color correcting unit for receiving display data sets in a plurality of layers, allowing individual control of a color of each of the layers, and outputting each of the inputted layers without performing any modification or after controlling the color of each of the layers; and a synthesizing unit for superimposing the display data sets in the individual layers outputted from the color correcting unit on each other and thereby generating new display data.

The arrangement allows an optimal color correction process to be performed for each of the plurality of layers before the synthesis and display of the layers. As a result, it becomes possible to perform optimal color correction with respect to any part of the screen.

In still another aspect, the present invention is a display processing apparatus for providing a plurality of display regions in a single screen and displaying an image in each of the display regions, the display processing apparatus comprising: a color correcting unit for performing color correction with respect to at least one of the plurality of display regions.

### BRIEF DESCRIPTION OF THE DRAWINGS

FIG. 1 is a block diagram showing a structure of a display processing apparatus according to a first embodiment of the present invention;

FIG. 2 is a block diagram showing a structure of a display processing apparatus according to a second embodiment of the present invention;

FIG. 3 is a block diagram showing a structure of a display processing apparatus according to a third embodiment of the present invention;

FIG. 4 is a view showing an example of the configuration of a color correction reducing layer;

FIG. 5 is a block diagram showing a structure of a display processing apparatus according to a fourth embodiment of the present invention; and

FIG. 6 is a block diagram showing a structure of a conventional display processing apparatus having a color correcting function.

### DETAILED DESCRIPTION OF THE PREFERRED EMBODIMENTS

Referring now to the drawings, the embodiments of the present invention will be described herein below.

### Embodiment 1

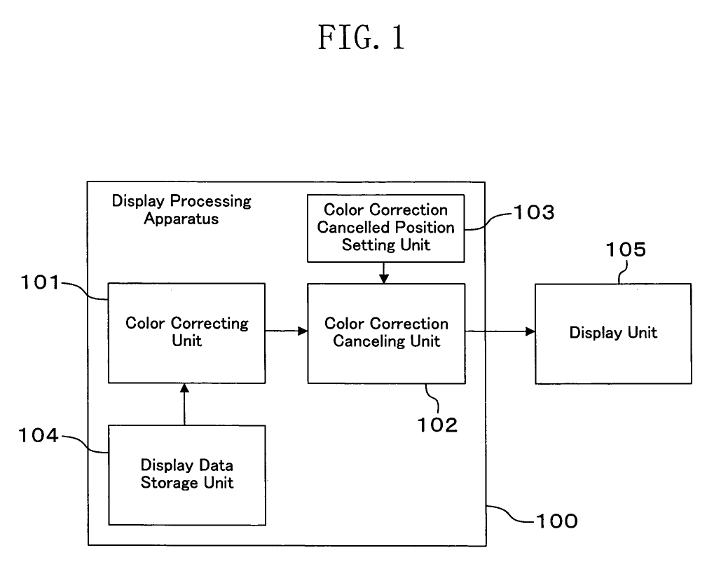

FIG. 1 is a block diagram showing a structure of a display processing apparatus 100 according to a first embodiment of the present invention. As shown in the drawing, the display processing apparatus 100, which is connected to a display unit 105, is comprised of: a color correcting unit 101; a color correction canceling unit 102; a color correction cancelled position setting unit 103; and a display data storage unit 104.

The display data storage unit 104 stores display data.

The color correcting unit 101 reads data stored in the display data storage unit 104 therefrom and performs color correction with respect to the read data by changing a specified parameter. Specifically, when a displayed image is dark, brightness control for brightening the display data is performed. As examples of the parameter used for the color correction, there can be listed a gamma value, a brightness, and the base values of the three primary colors (RGB) of red, green, and blue.

The color correction cancelled position setting unit 103 manages information (correction cancelled position information) indicative of the position of a part which does not require the color correction and outputs the correction cancelled position information to the color correction canceling unit 102. The correction cancelled position information can be obtained through, e.g., the user's specification of the coordinate values of the part or a window for which the color correction is not intended. Alternatively, it is also possible to preliminarily store coordinate values specifying a range outside the portion on which an image inputted from, e.g., a camera is displayed (or coordinate values specifying the portion on which the image inputted from the camera is displayed) in a register. In this case, coordinate values stored in the register may be set by an external CPU or the like or, alternatively, fixedly determined coordinate values may also be stored in the register.

The color correction canceling unit 102 receives the parameter used for the color correction and the color-corrected display data from the color correcting unit 101 and cancels the color correction of the display data which corresponds to the position shown by the correction cancelled position information received from the color correction cancelled position setting unit 103.

A description will be given next to the operation of the display processing apparatus 100. A consideration will be given to the case where, e.g., an image sensed by a camera is retrieved and displayed on one part of a display screen, i.e., the case where data on the image sensed by the camera is included in one part of the display data stored in the display data storage unit 104.

First, the color correcting unit 101 reads the data stored in the display data storage unit 104 therefrom. When the image sensed by the camera is, e.g., a low visibility image such as an image sensed in a dark environment at night, the color correcting unit 101 performs the color correction with respect to the read data. Specifically, the color correcting unit 101 performs, e.g., brightness control for brightening the entire display data to improve the visibility.

The color correction cancelled position setting unit 103 outputs the correction cancelled position information to the color correction canceling unit 102. As a result, the color correction canceling unit 102 cancels the color correction of the part (part not to be color-corrected) of the data (color-corrected display data) outputted from the color correcting unit 101 which corresponds to the correction cancelled position information.

Since the color correcting unit 101 performs color correction with respect to the entire display data (i.e., the entire screen), when the data from the color correcting unit 101 is outputted without any modification to the display unit 105, the part (part which does not require the color correction) other than the image sensed by the camera has an excessively high brightness. This lowers the visibility and renders the screen hard to be viewed. In the display processing apparatus 100, however, the color correction of the part which does not require the color correction is cancelled so that the part other than the image sensed by the camera has a visible brightness and the entire screen retains a sufficient visibility.

Thus, even when the color correction is performed to improve the visibility of one part of the screen, the present embodiment prevents the lowering of the visibility of the other part which does not require the color correction.

### Embodiment 2

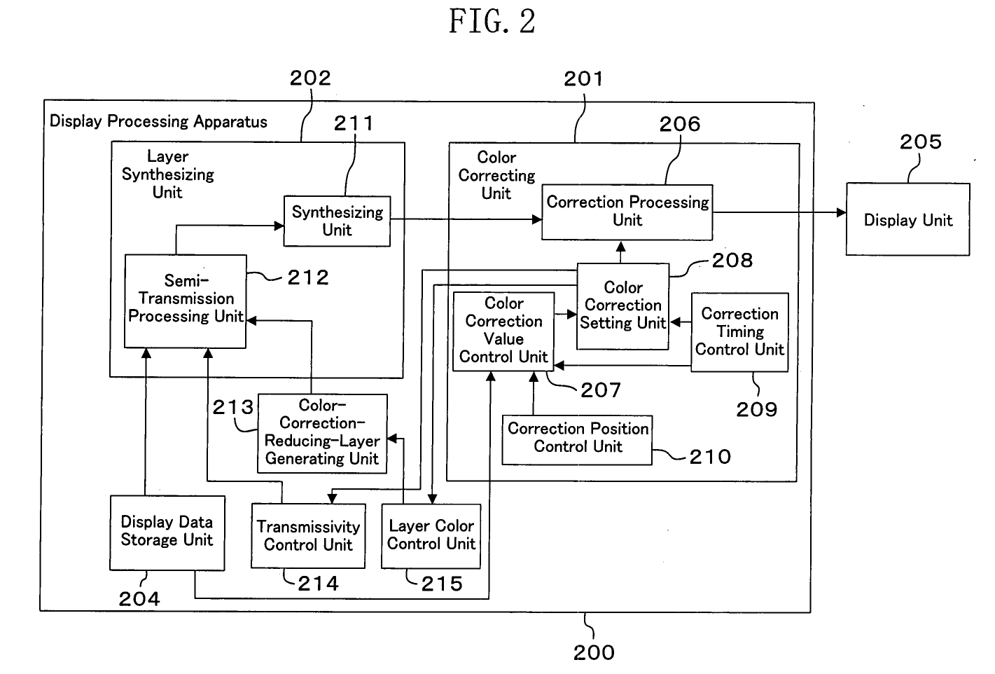

FIG. 2 is a block diagram showing a structure of a display processing apparatus 200 according to a second embodiment of the present invention. As shown in the drawing, the display processing apparatus 200, which is connected to a display unit 205, comprises: a color correcting unit 201; a layer synthesizing unit 202; a display data storage unit 204; a color-correction-reducing-layer generating unit 213; a transmissivity control unit 214; and a layer color control unit 215.

The display data storage unit 204 stores display data in a plurality of layers.

The layer synthesizing unit 202 comprises: a synthesizing unit 211; and a semi-transmission processing unit 212 and performs a process of superimposing the plurality of layers on each other. The semi-transmission processing unit 212 performs a semi-transmission process with respect to each of the plurality of layers such that each of them has a transmissivity (which will be described later) calculated by the transmissivity control unit 214. The synthesizing unit 211 performs the process of superimposing the plurality of layers on each other to which the semi-transmission processing unit 212 on each other has performed the semi-transmission process.

The color correcting unit 201 comprises: a correction processing unit 206; a color correction value control unit 207; a color correction setting unit 208; a correction timing control unit 209; and a correction position control unit 210 and performs the color correction of a screen.

The correction position control unit 210 outputs information indicative of a position to be color-corrected on the screen to the color correction value control unit 207.

The color correction value control unit 207 reads data corresponding to the position indicated by the correction position control unit 210 from the display data storage unit 204, while receiving a timing control signal indicative of the timing for calculating a color correction parameter, calculates the color correction parameter with the calculation timing, and outputs the calculated color correction parameter to the color correction setting unit 208.

For the calculation of the color correction parameter in the color correction value control unit 207, there can be adopted a method which evens out, e.g., when a brightness has a locally partial distribution, the distribution of the brightness, a method which uniquely calculates the color correction parameter by using such an arithmetic expression as to multiply a brightness distribution by a Gaussian distribution, or the like. The selection of a calculation method may be made appropriately in accordance with the application of the display processing apparatus 200, an image be displayed, and equipment to which the display processing apparatus 200 is connected, such as a camera.

The setting of the color correction parameter by the color correction value control unit 207 may also be performed such that the calculated color correction parameter is outputted directly to the color correction setting unit 208 or that the calculated color correction parameter is changed stepwise from the current value to a new value given by the color correction value control unit 207 and the finally obtained value is outputted to the color correction setting unit 208.

The color correction setting unit 208 receives the timing control signal indicative of the timing for calculating the color correction parameter from the correction timing control unit 209 and sets the color correction parameter to the correction processing unit 206 with the calculation timing. Specifically, when the calculated color correction parameter is given by the color correction value control unit 207 without any modification, the color correction setting unit 208 stepwise changes the color correction parameter from the current value to a new value and sets the finally obtained value to the correction processing unit 206. When the color correction value control unit 207 stepwise updates the color correction parameter and gives the updated color correction parameter, the color correction setting unit 208 sets the given color correction parameter without any modification to the correction processing unit 206. As a result, the color correction is performed stepwise.

The setting of the color correction parameter to the correction processing unit 206 need not necessarily be performed for every one frame of the display data. The setting of the color correction parameter may also be performed for, e.g., every several frames (i.e., at each specified time interval) in accordance with the application of the apparatus.

The correction timing control unit 209 controls the timing with which the color correction value control unit 207 calculates the color correction parameter and the timing with which the color correction setting unit 208 sets the parameter by outputting the timing control signal. The timing differs depending on a screen update rate and the application. However, the timing may also be determined uniquely such as at an interval of 1 second or for every 30 frames.

The correction processing unit 206 performs a color correction process based on the color correction parameter set by the color correction setting unit 208.

The layer color control unit 215 sets the color of a color correction reducing layer (which will be described later) based on the color correction parameter outputted from the color correction setting unit 208. The color correction reducing layer is defined herein as a layer to be superimposed on the part of the screen which is not to be color-corrected to reduce the effect of the color correction.

To determine the color of the color correction reducing layer, the layer color control unit 215 sets a synthesized color of red when the color correction is performed only to, e.g., red color. When the color correction is performed only to, e.g., green and blue colors other than the red color, respective synthesized colors of green and blue are set. That is, the color of the color correction reducing layer is determined by combining the three primary colors of red, green, and blue. When the color correction is brightness control, black color is set when the brightness control is in a brightening direction and white color is set when the brightness control is in a darkening direction.

Besides, there can also be considered another method which compares a given color (e.g., red color) after the correction with a color (e.g., pink color) before the correction and performs conversion such that the error therebetween falls within a determined range, thereby minimizing the effect of the color correction.

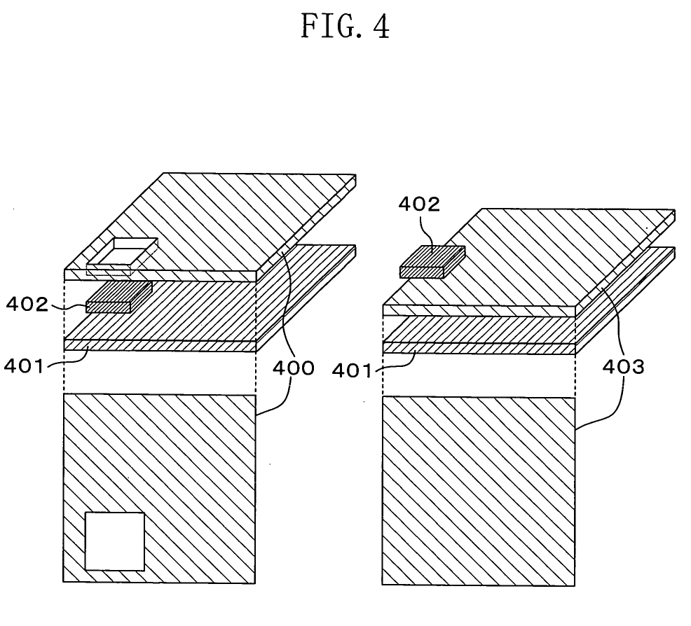

The color-correction-reducing-layer generating unit 213 generates the color correction reducing layer based on the color set by the layer color control unit 215. Specifically, the color correction reducing layer generated by the color-correction-reducing-layer generating unit 213 may conceivably have either of the configurations shown as examples in FIG. 4. In FIG. 4, 400 and 403 denote the color correction reducing layers, 401 denotes a layer to which the color correction is not performed, and 402 denotes a layer to which the color correction is performed.

The color correction reducing layer shown on the left-hand side of FIG. 4 has a configuration from which the portion corresponding to the layer to be color-corrected has been cut away. When the color correction reducing layer is placed between the layer (which may be single or plural) to be color-corrected and the layer not to be color-corrected as shown on the right-hand side of FIG. 4, the color correction reducing layer having the same configuration as the layer not to be color-corrected is used.

The transmissivity control unit 214 determines the transmissivity of the color correction reducing layer based on the color correction parameter outputted from the color correction setting unit 208 when the layer synthesizing unit 202 performs the process of superimposing the color correction reducing layer and outputs information indicative of the determined transmissivity to the semi-transmission processing unit 212.

As an example of a method for determining the transmissivity in the transmissivity control unit 214, there can be considered one which divides color changes resulting from the color correction into levels based on the post-correction color of a given reference color (e.g., red color) and uniquely determines a 90% transmissivity when a color change is on a low level or a 50% transmissivity when a color change is on a high level. It is also possible to calculate a value which adjusts the gamma value to 1 such as by, e.g., gamma correction, not to uniquely determine the transmissivity based on the color change level. However, since the optimal gamma value differs depending on the display unit, an objective gamma value is not limited to 1.

A description will be given next to the operation of the display processing apparatus 200. A consideration will be given to the case where, e.g., an image sensed by a camera is retrieved into one layer or one part of the display screen and displayed, i.e., where image data sensed by the camera is included in one part of the display data stored in the display data storage unit 204. When the image data sensed by the camera is a low visibility image, such as an image sensed at night, it is necessary to render the image easier to be viewed by conducting optimal color correction, which is brightness control for brightening the display data in this case, with respect to the camera image and thereby improve the visibility.

First, the correction position control unit 210 outputs information indicative of a position to be color-corrected on a screen to the color correction value control unit 207. The color correction value control unit 207 reads the display data on the camera image retrieved into one layer or one part of the screen from the display data storage unit 204 based on the information outputted from the correction position control unit 210. Then, the color correction value control unit 207 calculates the color correction parameter which is optimal for the part based on the display data and outputs the calculated color correction parameter to the color correction setting unit 208. The timing with which the color correction value control unit 207 calculates the color correction parameter is the timing indicated by the correction timing control unit 209,

The color correction setting unit 208 stepwise changes, a plurality of times, the current value of the color correction parameter calculated by the color correction value control unit 207 with the timing for calculating the color correction parameter reported from the correction timing control unit 209 and sets the finally obtained value to the correction processing unit 206.

On the other hand, the layer color control unit 215 receives the color correction parameter outputted from the color correction setting unit 208 and determines the color of the color correction reducing layer to be generated in the color-correction-reducing-layer generating unit 213. As a result, the color-correction-reducing-layer generating unit 213 generates the color correction reducing layer in the color determined by the layer color control unit 215. The transmissivity control unit 214 determines the transmissivity of the color correction reducing layer and outputs the information thereon to the semi-transmission processing unit 212.

The semi-transmission processing unit 212 performs a semi-transmission process with respect to each of the plurality of layers read from the display data storage unit 204 and the color correction reducing layer generated by the color-correction-reducing-layer generating unit 213. The synthesizing unit 211 synthesizes the individual layers to which the semi-transmission processing unit 212 has performed the semi-transmission process and outputs the resulting data to the correction processing unit 206. The correction processing unit 206 performs a color correction process based on the color correction parameter set by the color correction setting unit 208.

Thus, since the color correction reducing layer for reducing the effect of the color correction is synthesized with the layers of the original image, the lowering of the visibility of the part which does not require the color correction can be reduced even when the color correction is performed with respect to the display data resulting from the synthesis.

By setting the time interval between the color corrections in accordance with the application of the apparatus and gradually changing the color correction parameter stepwise, a sudden change in the brightness of the screen can be prevented.

Since the color and transmissivity of the color correction reducing layer are determined based on the color correction parameter, the reducing process can be performed even to the portion to which the color correction is not performed in synchronization with the color correction process and therefore the color correction reduction can be performed with proper timing.

### Embodiment 3

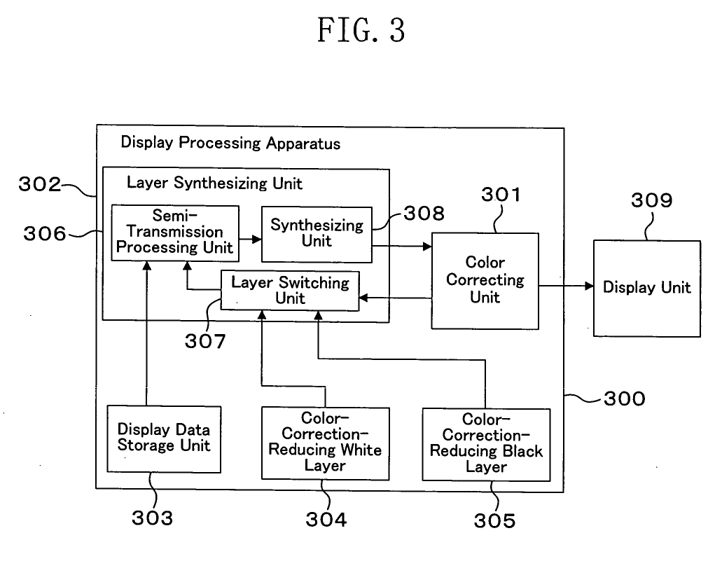

FIG. 3 is a block diagram showing a structure of a display processing apparatus 300 according to a third embodiment of the present invention. As shown in the drawing, the display processing apparatus 300, which is connected to a display unit 309, comprises: a color correcting unit 301; a layer synthesizing unit 302; a display data storage unit 303; a color-correction-reducing white layer 304; and a color-correction-reducing black layer 305.

The display data storage unit 303 stores display data in a plurality of layers.

The color-correction-reducing white layer 304 stores data in the layer set to white color.

The color-correction-reducing black layer 305 stores data in the layer set to black color.

The color correcting unit 301 performs color correction with respect to inputted image data and outputs information indicative of whether the color correction is for increasing a brightness or for reducing the brightness.

The layer synthesizing unit 302 comprises: a semi-transmission processing unit 306; a layer switching unit 307; and a synthesizing unit 308 and performs a process of superimposing a plurality of layers on each other.

The layer switching unit 307 selects either of the data in the color-correction-reducing white layer 304 and the data in the color-correction-reducing black layer 305 and outputs the selected data to the semi-transmission processing unit 306. Specifically, the layer switching unit 307 selects the color-correction-reducing black layer 305 when the color correction performed by the color correcting unit 301 is for increasing the brightness and selects the color-correction-reducing white layer 304 when the color correction performed by the color correcting unit 301 is conversely for reducing the brightness.

The semi-transmission processing unit 306 performs the semi-transmission process with respect to the plurality of layers such that each of the layers (display data) read from the display data storage unit 303 and the layer inputted via the layer switching unit 307 has a specified transmissivity.

The synthesizing unit 308 performs the process of superimposing the plurality of layers to which the semi-transmission processing unit 306 has performed the semi-transmission process.

In the display processing apparatus 300 described above, even when the color correction is in the brightening direction or in the darkening direction, the color of the color correction reducing layer can be switched in accordance with the direction of the color correction. As a result, it becomes possible to reduce the lowering of the visibility of the part which does not require the color correction.

### Embodiment 4

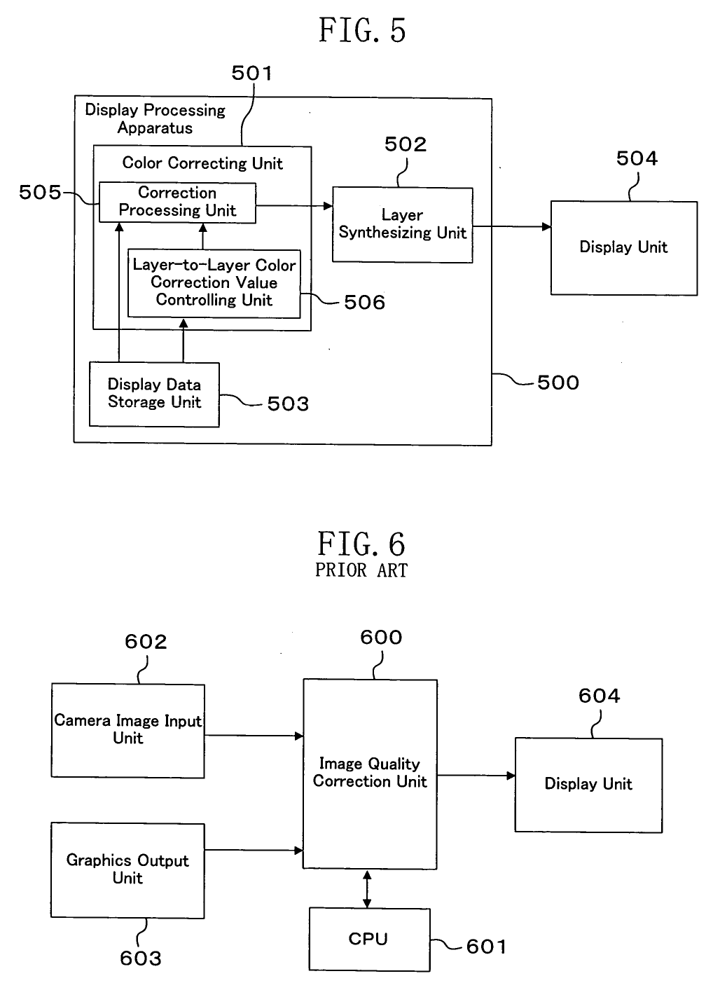

FIG. 5 is a block diagram showing a structure of a display processing apparatus 500 according to a fourth embodiment of the present invention. The display processing apparatus 500 is an example of a display processing apparatus which requires multi-layer display. As shown in the drawing, the display processing apparatus 500, which is connected to a display unit 504, comprises: a color correcting unit 501; a layer synthesizing unit 502; and a display data storage unit 503.

The display data storage unit 503 stores display data in a plurality of layers.

The color correcting unit 501 comprises: a correction processing unit 505; and a layer-to-layer color correction value control unit 506, reads data in the display data storage unit 504 therefrom, and performs color correction.

The layer-to-layer color correction value control unit 506 calculates a color correction parameter for performing optimal color correction for each of the layers required for display and individually controls the color correction for each of the layers. The correction processing unit 505 performs the color correction for each of the layers in accordance with the color correction parameter calculated for each of the layers by the layer-to-layer color correction value control unit 506. The correction processing unit 505 may output data in the current layer without any modification when the color correction parameter which does not change the current display state is given or may also perform the color correction (in which the color does not actually change) indicated by the given parameter and output the result of the color correction.

The layer synthesizing unit 502 performs a process of superimposing the plurality of layers required for display on each other.

In the display processing apparatus 500 described above, the color correction can be performed independently for each of the layers by assigning entirely different screens of, e.g., a graphic image and a camera input image to the different layers. This allows the optimal color correction to be performed with respect to one part (which is one layer in this case) of the screen without affecting the portion which does not require the color correction. Accordingly, when the visibility of the layer including a camera image is not high, only the layer can be corrected to an optimal color.

In the second embodiment when the color set in the layer color control unit 215 is selectively predetermined from several candidate colors, it is also possible to prepare a plurality of layers corresponding to the candidates in advance in the same manner as in, e.g., the display processing apparatus 300 shown in FIG. 3 and select one of the layers.

The color correction need not necessarily be performed at specified time intervals. For example, the color correction may also be performed when the luminance of the display data inputted from, e.g., a camera or the like exceeds a specified threshold.

The gamma value, the brightness, and the base values of RGB described as parameters used for the color correction are only illustrative. The parameters used for the color correction are not limited thereto provided that they are parameters which change the visibility of a screen.

Thus, the display processing apparatus according to the present invention has the effect of successfully preventing or reducing the lowering of the visibility of the part of a screen which does not require color correction even when the color correction is performed to improve the visibility of one part of the screen and is therefore useful as a display processing apparatus having a color correcting function for improving the visibility of display data or the like.

What is claimed is:

1. A display processing apparatus comprising:
a color correcting unit for performing color correction with respect to display data;
a color correction cancelled position setting unit for outputting correction cancelled position information indicative of a position of a part of the display data which does not require the color correction; and
a color correction canceling unit for canceling the color correction of the part of the display data color-corrected by the color correcting unit which corresponds to the correction cancelled position information.

2. A display processing apparatus comprising:
a semi-transmission processing unit for receiving display data sets in a plurality of layers and performing a semi-transmission process to adjust a transmissivity of each of the inputted layers to a specified value;
a synthesizing unit for superimposing the display data sets in the individual layers on each other to which the semi-transmission processing unit has performed the semi-transmission process and thereby generating new display data;
a color correcting unit for performing color correction with respect to the new display data;
a correction position control unit for outputting correction cancelled position information indicative of a position of a part of the new display data which does not require the color correction; and
a color-correction-reducing-layer generating unit for outputting data in a color correction reducing layer composed of data for reducing an effect of the color correction at the part corresponding to the correction cancelled position information.

3. The display processing apparatus of claim 2, wherein the color-correction-reducing-layer generating unit selects either of data in a color correction reducing layer composed of black color data and data in a color correction reducing layer composed of white color data and outputs the selected data to the semi-transmission processing unit.

4. The display processing apparatus of claim 2, wherein
the color correcting unit performs the color correction by changing a value of a specified correction parameter for changing a visibility of displayed data and outputs the correction parameter to the semi-transmission processing unit and
the semi-transmission processing unit determines the transmissivity in accordance with the correction parameter outputted from the color correcting unit.

5. The display processing apparatus of claim 2, further comprising:
a layer color control unit for determining, in accordance with the color correction performed in the color correcting unit, a color of the color correction reducing layer by combining three primary colors of red, green, and blue, wherein
the color-correction-reducing-layer generating unit generates the color correction reducing layer in the color determined by the layer color control unit.

6. The display processing apparatus of claim 1, wherein
the display data is motion-picture data and
the color correcting unit performs the color correction at a specified time interval.

7. The display processing apparatus of claim 2, wherein
the display data is motion-picture data and
the color correcting unit performs the color correction at a specified time interval.

8. The display processing apparatus of claim 1, wherein
the display data is motion-picture data and
the color correcting unit stepwise performs the color correction till a finally corrected state is reached.

9. The display processing apparatus of claim 2, wherein
the display data is motion-picture data and
the color correcting unit stepwise performs the color correction till a finally corrected state is reached.

10. The display processing apparatus of claim 2, wherein
the synthesizing unit performs the superimposition in synchronization with the color correction in the color correcting unit.

11. A display processing apparatus comprising:
a color correcting unit for receiving display data sets in a plurality of layers, allowing individual control of a color of each of the layers and outputting each of the inputted layers without performing any modification or after controlling the color of each of the layers; and
a synthesizing unit for superimposing the display data sets in the individual layers outputted from the color correcting unit on each other and thereby generating new display data.

12. A display processing apparatus for providing a plurality of display regions in a single screen and displaying an image in each of the display regions, the display processing apparatus comprising:
a color correcting unit for performing color correction with respect to at least one of the plurality of display regions.
